(19) United States
(12) Patent Application Publication
(10) Pub. No.: US 2009/0166601 A1
(43) Pub. Date: Jul. 2, 2009

(54) Non-volatile programmable variable resistance element

(75) Inventors: Wolodymyr Czubatyj, Warren, MI (US); Guy Wicker, Southfield, MI (US)

Correspondence Address: Ovonyx, Inc, 2956 Waterview Drive, Rochester Hills, MI, 48309, US

(73) Assignee: Ovonyx, Inc.

(21) Appl. No.: 12/006,390

(22) Filed: Jan. 2, 2008

(51) Int. Cl. H01L 45/00

(52) U.S. Cl. 257/3; 257/E45.002

(57) ABSTRACT

A phase-change memory element exhibits a non-uniform temperature profile in the phase-change material, resulting in a non-uniform temperature profile. The non-uniform temperature profile causes non-uniform growth of a programmed volume, resulting in a gradual R-I characteristic. The phase-change material may be a chalcogenide material.

### FIELD OF THE INVENTION

The present invention is related to electrically programmable resistance memory. In particular, the present invention relates to phase-change memory.

### BACKGROUND OF THE INVENTION

Programmable resistance memory elements formed from materials that can be programmed to exhibit at least a high or low stable ohmic state are known in the art. Such programmable resistance elements may be programmed to a high resistance state to store, for example, a logic ONE data bit or programmed to a low resistance state to store a logic ZERO data bit.

One type of material that can be used as the memory material for programmable resistance elements is phase-change material. Phase-change materials may be programmed between a first structural state where the material is generally more amorphous (less ordered) and a second structural state where the material is generally more crystalline (more ordered). The term “amorphous”, as used herein, refers to a condition which is relatively structurally less ordered or more disordered than a single crystal and has a detectable characteristic, such as high electrical resistivity. The term “crystalline”, as used herein, refers to a condition which is relatively structurally more ordered than amorphous and has lower electrical resistivity than the amorphous state.

The phase-change materials may be programmed between different detectable states of local order across the entire spectrum between completely amorphous and completely crystalline states. That is, the programming of such materials is not required to take place between completely amorphous and completely crystalline states but rather the material can be programmed in incremental steps reflecting (1) changes of local order, or (2) changes in volume of two or more materials having different local order so as to provide a “gray scale” represented by a multiplicity of conditions of local order spanning the spectrum between the completely amorphous and the completely crystalline states. For example, phase-change materials may be programmed between different resistive states while in crystalline form.

A volume of phase-change material may be programmed between a more ordered, low resistance state and a less ordered, high resistance state. A volume of phase-change is capable of being transformed from a high resistance state to a low resistance state in response to the input of a single pulse of energy referred to as a “SET pulse”. The SET pulse is sufficient to transform the volume of memory material from the high resistance state to the low resistance state. It is believed that application of a SET pulse to the volume of memory material changes the local order of at least a portion of the volume of memory material. Specifically, it is believed that the SET pulse is sufficient to change at least a portion of the volume of memory material from a less-ordered amorphous state to a more-ordered crystalline state.

The volume of memory material is also capable of being transformed from the low resistance state to the high resistance state in response to the input of a single pulse of energy which is referred to as a “RESET pulse”. The RESET pulse is sufficient to transform the volume of memory material from the low resistance state to the high resistance state. While not wishing to be bound by theory, it is believed that application of a RESET pulse to the volume of memory material changes the local order of at least a portion of the volume of memory material. Specifically, it is believed that the RESET pulse is sufficient to change at least a portion of the volume of memory material from a more-ordered crystalline state to a less-ordered amorphous state.

The use of phase-change materials for electronic memory applications is known in the art. Phase-change materials and electrically programmable memory elements formed from such materials are disclosed, for example, in U.S. Pat. Nos. 5,166,758, 5,296,716, 5,414,271, 5,359,205, 5,341,328, 5,536,947, 5,534,712, 5,687,112, and 5,825,046 the disclosures of which are all incorporated by reference herein. Still another example of a phase-change memory element is provided in U.S. patent application Ser. No. 09/276,273, the disclosure of which is also incorporated herein by reference.

It is important to be able to accurately read the resistance states of programmable resistance elements which are arranged in a memory array. The present invention describes an apparatus and method for accurately determining the resistance states of programmable resistance elements arranged as memory cells in a memory array. Background art circuitry is provided in U.S. Pat. No. 4,272,833 which describes a reading apparatus based upon the variation in the threshold levels of memory elements, and U.S. Pat. No. 5,883,827 which describes an apparatus using a fixed resistance element to generate reference signals. Both U.S. Pat. No. 4,272,833 and U.S. Pat. No. 5,883,827 are incorporated by reference herein.

### SUMMARY OF THE INVENTION

A phase change memory in accordance with the principles of the present invention includes a volume of phase change material in electrical communication with two contacts and at least one thermal element in thermal communication with the volume of the phase change material. In one aspect of the invention, the thermal element may be situated to increase (relative to a memory without the thermal element) the volume fraction of phase change material that must be amorphized in order to yield a given resistance between the two electrodes.

A phase change memory in accordance with the principles of the present invention may be characterized by the amount of energy required to melt at least a portion of the phase change material proximate the area of a contact and the greater amount of energy required to melt enough of the material for the phase change material to reach a saturation resistance. The melt and saturation resistances are defined herein respectively as 0.5% and 90% of the maximum resistance exhibited by the phase change device. The current pulses corresponding to these energies are referred to herein, respectively, as I_{MELT} and I_{SAT}. In accordance with the principles of the present invention, a thermal element in thermal communication with the phase change material increases the difference between the energy corresponding to I_{MELT} and the energy corresponding to I_{SAT} while limiting I_{MELT} Limiting, that is, any increase in the energy required to melt at least a portion of phase change material proximate to a contact.

In another aspect of a phase change memory in accordance with the principles of the present invention, a thermal element is placed in thermal communication with phase change material in a manner that discourages amorphization of a least resistance path cross section of the phase change material. As employed herein, the term least resistance path cross section refers to a cross section of the path of least electrical resistance from one electrode to another across the phase change material. The area of this critical cross section is less than a cross section of the entire phase change volume but at least as great as the minimal cross section required to carry a current sufficient to drive the phase change material to saturation using a predetermined current pulse-width.

One or more thermal elements are employed in a phase change memory in accordance with the principles of the present invention to increase the difference in amplitude between current pulses within the I_{MELT} to Iₛₐₜ range for corresponding increases in device resistances. By increasing differences in programming current within this range, current/resistance pairs may be more readily distinguishable, thereby enhancing the ability to store multiple levels of information within a single phase change memory element.

In illustrative embodiments, the thermal elements may be dissipating or conserving elements, acting respectively, as heat sinks or as thermal insulation. In such embodiments, the thermal element(s) is arranged to induce a thermal profile within the phase change material that includes one or more thermal gradients. The thermal elements may be arranged to induce gradients that increase the volume percentage of phase change material that is amorphized for a given resistance change in the device's RESET current regime.

### BRIEF DESCRIPTION OF THE DRAWINGS

FIGS. 1A and 1B are illustrative graphs of current pulse amplitude versus resistance for a phase change memory device;

FIGS. 2A through 2E are conceptual cross sections of a phase change material's amorphization;

FIGS. 3A and 3B are cross sectional views of a phase change memory that employs a thermal element in accordance with the principles of the present invention;

FIGS. 4A through 4C show an embodiment of a memory device useful for establishing a non-uniform temperature profile about an area of contact; and

FIGS. 5A through 5F′ show non-uniform temperature profile about the area of contact for a phase-change memory element.

### DETAILED DESCRIPTION

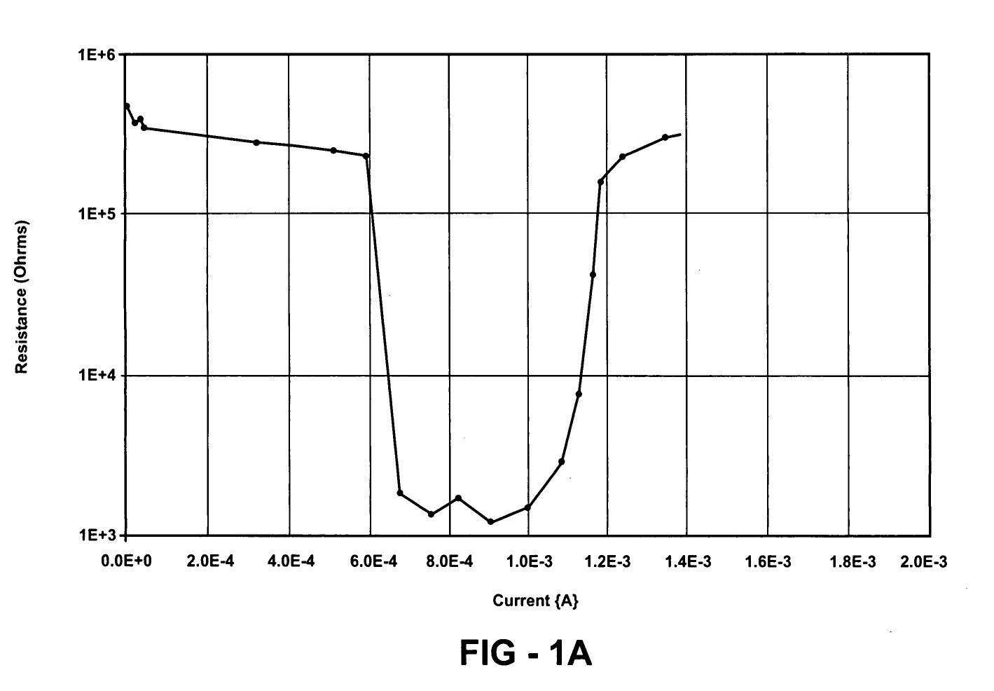

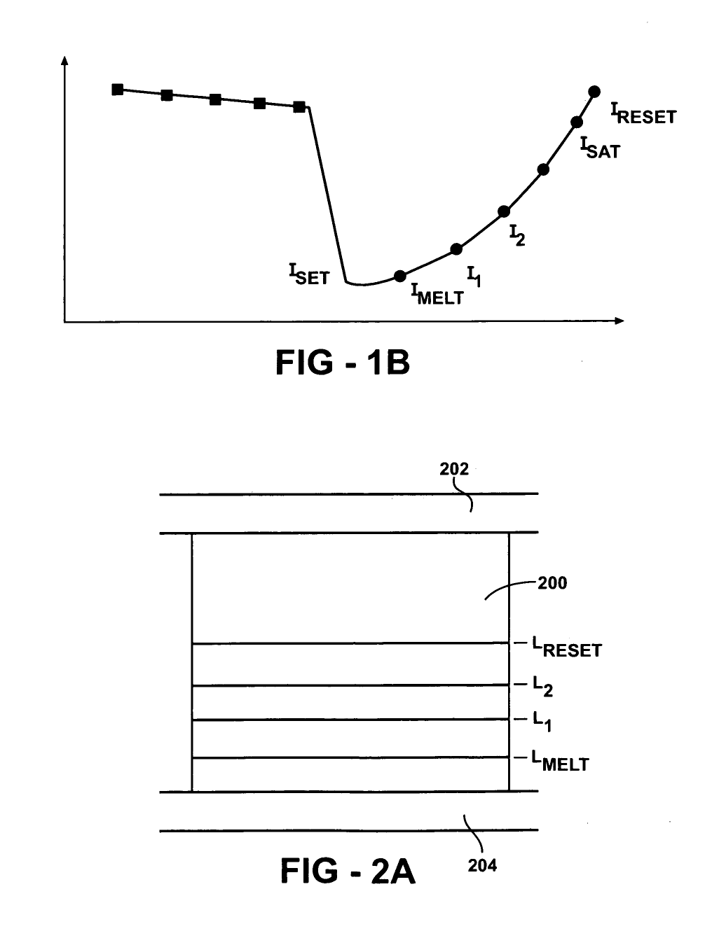

FIG. 1A is a graph of resistance vs. current pulse amplitude, such as may be produced by a typical phase change memory. The ordinate of the graph represents the electrical resistance across a volume of phase change material as measured at two electrodes in electrical communication through the phase change material. The abscissa represents the various magnitudes of current pulses that may be applied to the phase change device. In this depiction, we assume that the current pulses are of equal duration and similar shape (substantially square). Consequently, current pulse magnitude acts as a proxy for the energy content of a pulse.

At the leftmost extreme of the graph the resistance is a relatively high 1 MΩ, characteristic of a RESET condition for the phase change device in which it was left. The device could also have been left in a SET state. A current pulse of amplitude I_{SET} crystallizes a sufficient amount of phase change material within the phase change device to provide a relatively low resistance path through the phase change material from one electrode to another. Shorter programming current pulses may be applied to the phase change device in an attempt to increase the resistance of the device. In the illustrative embodiment of FIG. 1A a current pulse of any amplitude above Iset and up to I_{MELT} yields insignificant change in the resistance of the phase change device.

At the amplitude of I_{MELT}, the energy content of a current pulse is sufficient to melt at least a portion of phase change material proximate the area of contact between the phase change material and an electrode. Because the relatively short duration of a programming current pulse (50 nanoseconds in this illustrative embodiment) allows the melted material to cool before significant crystallization of the melted material may occur, a portion of phase change material in the current path between the electrodes is transformed by the current pulse I_{MELT} to an amorphous state characterized by a relatively high electrical resistance. The value of increased resistance selected to define I_{MELT} may be somewhat arbitrary. For the sake of this discussion, a resistance increase from the low, SET, resistance, to 0.5% of the high, RESET, resistance corresponds to the melt resistance, R_{MELT}, and melt current, I_{MELT}. At the other extreme of amorphization, the saturation resistance is chosen as 90% of the RESET resistance and saturation current, I_{SAT}, the corresponding current pulse amplitude.

As can be seen from the graph of FIG. 1A, the transition from I_{MELT} to Isat is abrupt. In this illustrative embodiment, the resistance of the phase change device changes from 5 KΩ to 900 KΩ in response to a difference in current pulse amplitude of only 0.2 mA. To put this in perspective, a 20% increase in current amplitude yields an 18,000% increase in resistance. Because the SET condition exhibits a resistance of only 2.0 KΩ and the RESET condition exhibits a resistance, 1 MΩ, nearly three orders of magnitude greater than the SET condition, it is very easy to distinguish the two states. The relatively miniscule 0.2 mA difference in programming current pulse amplitude responsible for that enormous difference in resistance provides far less margin for distinguishing the state of the phase change device.

This narrow range of programming pulse amplitudes does not pose a problem for binary operation. Even with wide variation in device-to-device characteristics, the differences in programming current and resultant resistance values are relatively easy to distinguish. However, for multi-level operation in which more than two states, corresponding to more than one bit of information, may be stored within a single phase-change cell, the relatively narrow current pulse amplitude window does pose a problem.

That is, if, in order to increase the information storage density of the phase change device, the range of programming currents and resultant resistances are divided into sub-ranges, with current amplitudes intermediate to I_{MELT} and I_{SAT} assigned logic values (for example, R1 and R2, assigned logic values two and three, respectively), device variations could easily cause a slight shift in current amplitude response that could lead to an errant resistance reading for a given programming pulse. The resistance resulting from a programming pulse I1 may be misread as the resistance resulting from a programming pulse I_{MELT}, for example.

In order to increase the error margin and thereby make multi-level storage more practical, even with somewhat relaxed manufacturing margins, it is essential to extend the range of current amplitudes, I_{MELT} to Iₛₐₜ, corresponding to the range of resistance values, R_{MELT}-Rₛₐₜ. Ideally, one would extend this range while minimizing any increase in total energy required to program the phase change device.

The RI graph of FIG. 1B illustrates a resistance/current profile that would be much more desirable for multi-level memory operation. In this illustrative embodiment the transition between I_{MELT} and Iₛₐₜ is much more gradual. A more gradual slope such as this allows for much easier discrimination of multiple logic levels, as illustrated by the greater separation between current pulses I1 and I2.

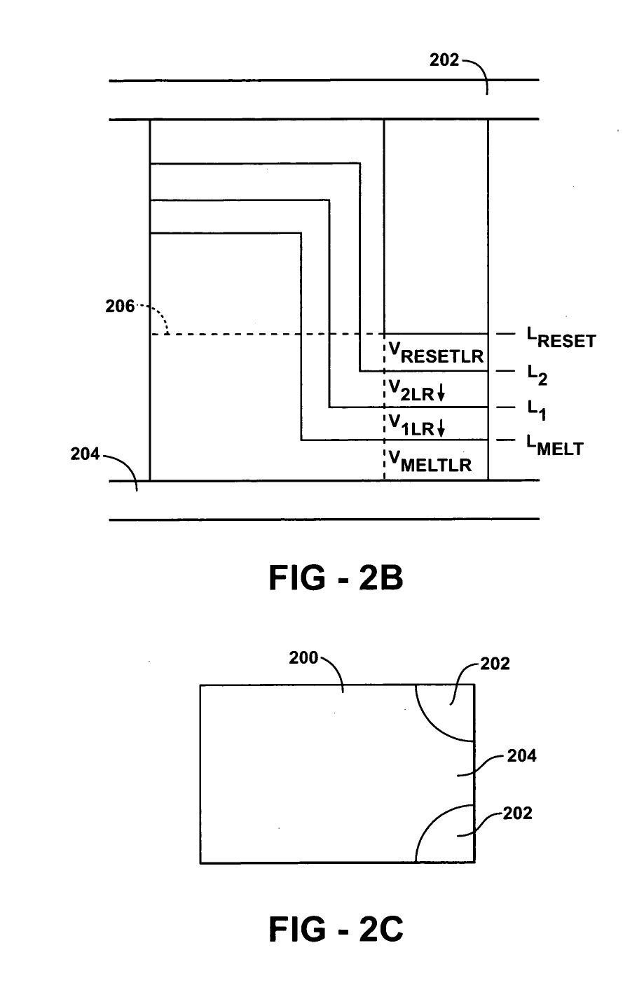

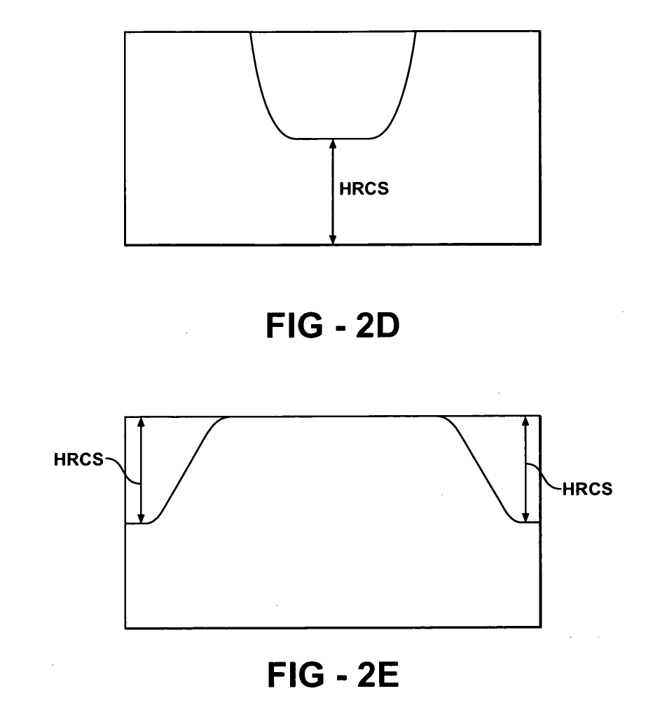

For the purpose of illustration, the cross-sectional view of FIG. 2A presents a highly simplified conceptual view of phase change material and the phase change process. A volume of phase change material 200 is electrically coupled to top 202 and bottom 204 electrodes. In this conceptual depiction, application of a current pulse I_{MELT} uniformly transforms a layer L_{MELT} of phase change material across a cross section of the phase change volume. Such uniform transformation, although not actually seen in practice, represents the lowest-energy transformation possible for a given resistance change between the electrodes 202 and 204. Because vertical cross sections of the material 200 are uniform throughout the volume, there is no path of least resistance between the electrodes 202 and 204.

Another way to visualize the transformation process is to realize that all the energy delivered to the volume 200 in the form of programming pulse I_{MELT} has gone into transforming the minimal volume of phase change material, V_{MELT}, to yield a resistance R_{MELT}. In a real device the pictorial layers represent “volume fractions” of the phase change alloy's total volume. And in reality, any non-uniformity in the cross section, any “bump” in the layer L_{MELT}, would necessarily include an area of lower resistance, through which current between the electrodes 202 and 204 would preferentially flow: a path of least resistance.

Similarly, current pulses I1, I2 of greater amplitude would yield volume fraction changes, symbolized by layers L1, L2 of amorphized phase change material with corresponding resistances R1, R2. Each amorphization step for each programming current amplitude increase, is the minimal increase resulting from the amorphization of additional phase change material. Reaching a resistance level Rₛₐₜ, corresponding to the application of a programming current Iₛₐₜ, would therefore require the minimal increase in energy input and the difference in amplitude between I_{MELT} and Iₛₐₜ would be minimal.

Recognizing that greater energy differences and, concomitantly, greater differences in programming current amplitudes, may be associated with imposing a non-uniformity on the minimal energy amorphization layers (e.g. L_{MELT}, L₁, L₂, L_{RESET}) depicted in FIG. 2A, a phase change memory in accordance with the principles of the present invention alters the thermal environment of the phase change volume 200 to create, or to enhance, non-uniformities in the phase change amorphization layers.

By manipulating the thermal environment of a phase change memory in accordance with the principles of the present invention, phase change memories exhibit a broader range of programming current values between I_{MELT} and Iₛₐₜ, thereby easing the process of discriminating the various resistance levels associated with a multi-level phase-change memory.

At the same time, a great deal of effort has been expended in attempts at reducing the energy required to program a phase change memory. A phase change memory in accordance with the principles of the present invention manipulates the thermal environment of the phase change volume 200 to minimize the total energy (current amplitude) required to program the device. A phase change memory in accordance with the principles of the present invention employs one or more thermal elements to increase the difference between I_{MELT} and Iₛₐₜ while, at the same time, minimizing both I_{MELT} and Iₛₐₜ. This process may be visualized as a “flattening” of the I/R curve from I_{MELT} to Iₛₐₜ in which I_{MELT} is substantially unchanged and Iₛₐₜ is increased to improve the discrimination of memory states.

A phase change memory in accordance with the principles of the present invention includes a volume of phase change material in electrical communication with two contacts and at least one thermal element in thermal communication with the volume of the phase change material. The thermal element is situated to increase the volume fraction of phase change material that must be amorphized in order to yield a given resistance between the two electrodes. The cross sectional diagram of FIG. 2B illustrates, in a simplified conceptual manner, the maximization of the volume fraction of phase change material amorphized for a given resistance in accordance with the principles of the present invention. In illustrative embodiments, the “given resistance” is the saturation or RESET resistance of the device.

In this illustrative embodiment, just as in the minimal energy case described in the discussion related to FIG. 2A, a minimal volume, V_{MELT}, of phase change material is amorphized to yield a resistance R_{MELT}. Unlike the minimal energy case set forth in relation to FIG. 2A, however, subsequent current pulses I₁, I₂, and Iₛₐₜ, amorphize non-uniform cross sections of the phase change volume 200, yielding programmed volumes V₁, V₂, and V_{RESET}, with corresponding resistances R₁, R₂, and R_{RESET}.

In this conceptual representation, Vₛₐₜ is the maximum volume of phase change material that can be amorphized to yield a value of Rₛₐₜ between the electrodes 202 and 204. In this illustrative embodiment, the increase in programmed volume for each intermediate value of resistance is substantially equal, so that, for example, the difference between V₁ and V_{MELT} is substantially equal to the difference between V₁ and V₂, which is substantially equal to the difference between V₂ and V_{RESET}. Additionally, the increases in programmed volumes in the path of least resistance are substantially equal, so that the difference between V_{MELTLR} and V_{1LR} is approximately equal to the difference between V_{1LR} and V_{2LR} and between V_{2LR} and V_{RESETLR}. Because substantially more phase change material is amorphized (V_{ADD}, above the broken line 206) to reach Rₛₐₜ, the corresponding current amplitude Iₛₐₜ is also increased.

Because the volume differences are substantially equal, the spacings between the corresponding resistances are also substantially equal. As will be described in greater detail in the discussion below, non-uniformities in the thermal profile of the phase change volume 200, established by thermal elements in accordance with the principles of the present invention, yield volume amorphization non-uniformities in the phase change material to increase the difference between I_{MELT} and I_{RESET} for a volume of phase change material.

In the illustrative embodiment of FIG. 2B the thickness of phase change material that yields a RESET resistance R_{RESET} of 1 MΩ is approximately 1,000 Å. The cross section must be of small area to minimize the RESET current I_{RESET}. The addition of thermal elements, insulating elements in particular, may allow for a reduction in I_{MELT} and, in combination with the effects of other thermal elements that maintain or increase the magnitude of I_{RESET}, a phase change memory in accordance with the principles of the present invention may “stretch” the segment of the device's I/R curve between I_{MELT} and I_{RESET} and thereby provide for greater discrimination in logic levels.

With one or more thermal elements placed in thermal communication with a device's phase change material in a manner that discourages amorphization of a portion of the phase change material, the thermal element(s) delays the formation of a high-resistance cross-section between the device's electrodes, thereby increasing the range of current amplitudes between I_{MELT} and Iₛₐₜ. By increasing differences in programming current within this range, current/resistance pairs may be more readily distinguishable, thereby enhancing the ability to store multiple levels of information within a single phase change memory element.

As illustrated in the conceptual diagrams of FIGS. 2C through 2E, thermal elements may be coupled to the phase change volume in a manner that creates a wide variety of high resistance cross sections. In FIG. 2C, for example, thermal elements are positioned to preferentially amorphize phase change material so that the amorphized, high-resistance, region 200 encompasses the majority of the overall phase change volume. An area 202 remains substantially crystalline. In this illustrative embodiment, the last area of amorphization to reach a thickness sufficient to yield a resistance equal to the RESET resistance is the relatively narrow “beak” 204. In an illustrative embodiment, such a region would be approximately 1000 Å thick. Such an amorphization pattern may be induced by placing heat sinks proximate the phase change material at the top and bottom of the device.

FIG. 2D illustrates an embodiment in which the high-resistance cross-section HRCS is “filled in” at the central portion of the phase change volume. In FIG. 2E the high resistance cross section has been filled in at either extreme of the phase change volume.

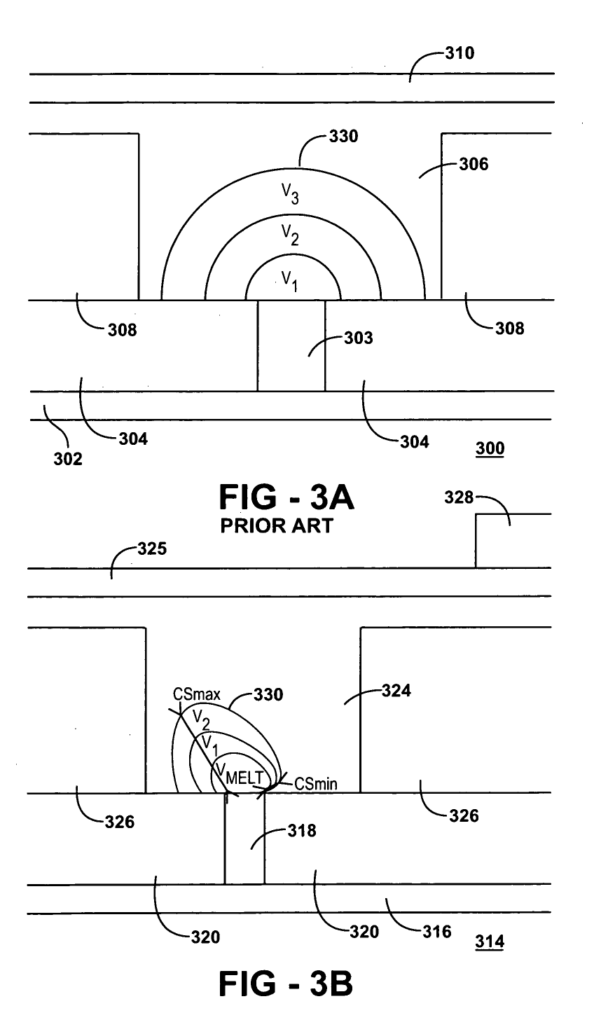

In the phase change memory of FIG. 3A a conventional device 300 includes a bottom electrode 302 in contact with a heater 303 that is surrounded by insulator 304. The heater 303 is characterized by a relatively high resistivity and provides localized heating of the phase change material. Heaters are known in the art and disclosed, for example, in U.S. Pat. No. 7,049,623, entitled, “VERTICALLY ELEVATED PORE PHASE CHANGE MEMORY,” issued to Tyler Lowrey, and U.S. Pat. No. 6,972,430, entitled, “SUBLITHOGRAPHIC CONTACT STRUCTURE, PHASE CHANGE MEMORY CELL WITH OPTIMIZED HEATER SHAPE, AND MANUFACTURING METHOD THEREOF,” issued to Casagrande et al, both of which are hereby incorporated by reference. The heater 303 makes contact with a volume of phase change material 306, such as a chalcogenide, formed in a pore of insulator material 308. The phase change material 306 is in electrical communication with a top electrode 310.

When a current pulse is applied to the memory device 300 energy is concentrated in the region around the interface between the heater 303 and phase change material 306. Consequently, phase change material is amorphized in a pattern that somewhat resembles the head of a mushroom. Current pulses of different amplitudes I1, I2, I3 . . . yield “mushroom heads” of different volumes V1, V2, V3, . . . . Eventually, the “mushroom head” of amorphized material reaches a point where the path of least resistance between the top 310 and bottom 302 electrodes, across the programmed volume 312, exhibits a resistance substantially equal to the reset resistance of the device.

In the somewhat stylized representation of FIG. 3A equal increments in energy (in the form of current-pulse amplitude) yield comparable increments in programmed volume. When current pulses of amplitude greater than I_{MELT} are reached, the corresponding volume of amorphized material rapidly reaches a volume corresponding to I_{RESET}. The depiction provided in FIG. 3A is intended to be a qualitative representation of a device in operation, not a definitive depiction of a device's actual operation.

By altering the thermal profile of a phase change memory in accordance with the principles of the present invention, we may extend the range of current pulse amplitudes falling between I_{MELT} and I_{RESET}, thereby providing for improved discrimination of intermediate memory states and allowing higher-density memory storage.

In the illustrative embodiment of FIG. 3B a memory device in accordance with the principles of the present invention 314 includes a bottom electrode 316 in contact with a heater 318 that is surrounded by insulator 320. The heater 318 makes contact with a volume of phase change material 324, such as a chalcogenide material, formed in a pore of insulator material 326. The phase change material 324 is in electrical communication with a top electrode 326. A heat sink 328 is positioned to induce non-uniformities in the thermal profile of the phase change material 324 and to thereby extend the range of current pulses between I_{MELT} and I_{RESET}.

In an illustrative embodiment a relatively heavy conductor, such as a top contact, may serve double duty as both an electrical channel for accessing the memory device 314 through the electrode 326 and as a heat sink 328 in thermal communication with the device. The somewhat stylized view of the progress of amorphization in FIG. 3B is meant to provide a visualization tool for understanding the gross effects of the application of one or more thermal gradients to the phase change material 324. It is not meant to provide a thoroughgoing analytical description of the process.

In this illustrative embodiment, as programming amplitudes are increased from IMELT to I1, I2, I3, instead of obtaining the familiar mushroom head amorphization volume illustrated in FIG. 3A, the programmed volume 30 is canted away from the heat sink 328. The non-uniformities of temperature within the phase change material 324 retard growth of the amorphization volume in the direction of the heat sink 328. Consequently, a greater amount of energy must be expended to amorphize a path of least resistance between the top and bottom electrodes 326, 316. Examination of the programmed volume 330 shows that, because of the distortions created by the imposed thermal gradient, a minimum cross section CS_{MIN} of the programmed volume between the top electrode and the heater (and, through the heater, the bottom electrode) yields a resistance less than the RESET resistance of the device 314 while, at the same time, a maximum cross section CS_{MAX} yields a resistance greater than the RESET resistance of the device.

Current will, of course, flow through the area of least resistance and the device resistance will be that exhibited by the area of least resistance. Because the heat sink will have little effect on the amorphization of material proximate the heater 318, the current pulse amplitude corresponding to I_{MELT} should be substantially equal to that of a similar device without the heat sink 328. However, the distortions of the programmed volume attendant the addition of the heat sink 328 will increase the value of Iₛₐₜ (and of currents intermediate to Iₛₐₜ), thereby extending the current range for corresponding values of R_{MELT} and Rₛₐₜ and affording greater discrimination of intermediate memory levels.

One or more additional areas or thicknesses of insulator material may be added to the device to further reduce overall current requirements for the device, to induce a thermal gradient upon a device's phase change material, or to impose a thermal gradient in cooperation with a heat sink. The insulator 330 of FIG. 3B, for example, is situated to enhance the thermal gradient established by the heat sink 328 and to thereby further extend the range of current pulse amplitudes between I_{MELT} and Iₛₐₜ, for example. Imposing a thermal gradient in this manner may be thought of in terms of approximating the increase in programmed volume described in the discussion related to FIG. 2B Any use of one or more thermal elements to shape the programming volume of a phase change material to expand the range of amplitudes of current pulses between I_{MELT} and Iₛₐₜ are contemplated within the scope of the present invention.

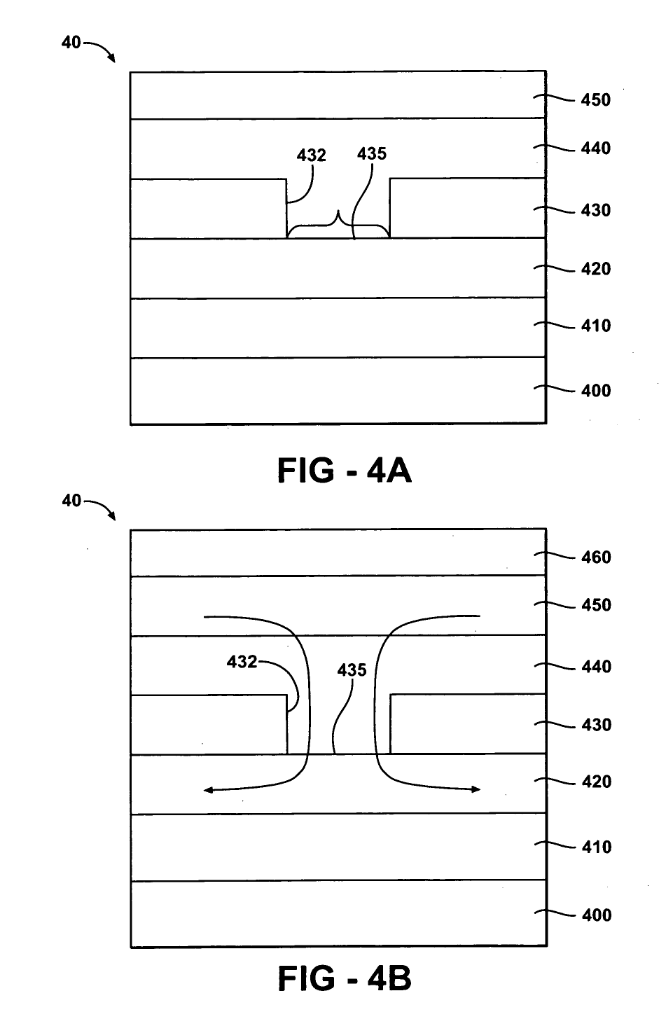

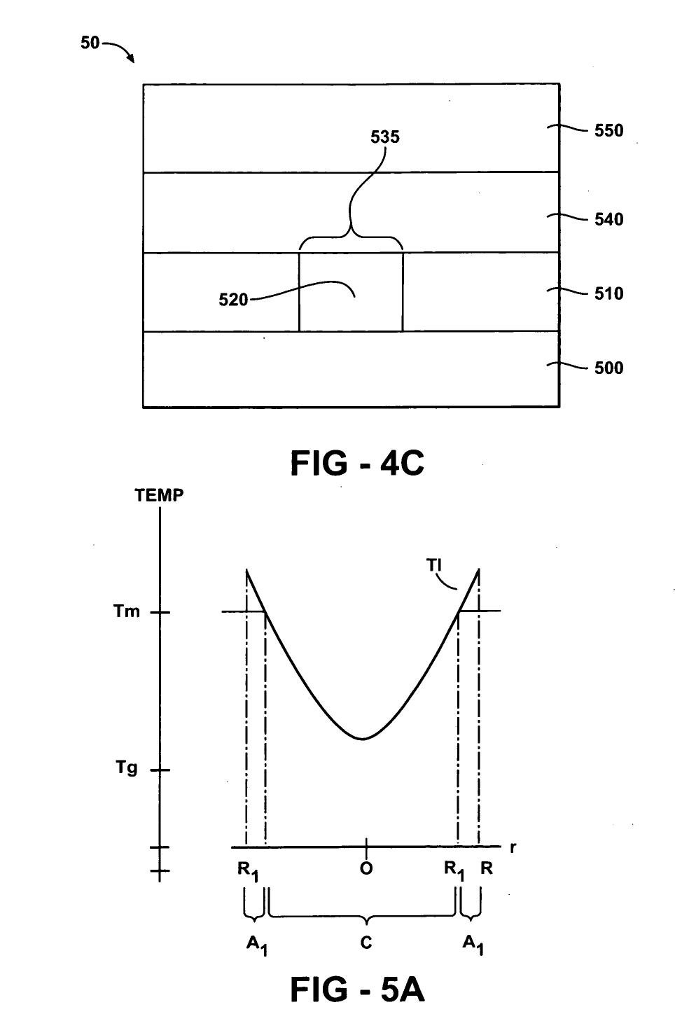

FIG. 4A shows an embodiment of a memory element 40 of the present invention. The memory element includes first dielectric layer 410 formed over a substrate 400. A first conductive layer 420 is formed over the first dielectric layer. The first conductive layer 420 serves as a first electrode (also referred to as a first electrical contact) for the memory element 40. A second dielectric layer 430 is formed over the first conductive layer 420. An opening 432 is formed in the second dielectric layer 430. A phase-change material 440 is deposited into the opening 432 such that the phase-change material 440 is in electrical communication with the first conductive layer 420. In the embodiment shown in FIG. 4A, the opening 432 is a hole (also referred to herein as a pore). However, in other embodiments of the invention, the opening 432 may, for example, be a trench. In the embodiment shown, the opening 432 is assumed to have a round cross section with a radius R. Hence, the area of contact 435 also has a radius R.

A second conductive layer 450 is deposited over the phase-change memory material 440. The second conductive layer serves as a second electrode (or second electrical contact) for the memory element. The first electrode 420 and the phase-change material 440 form a first area of contact 435 through which the first electrode 420 and the phase-change material electrically communicate.

At least a portion of the phase-change material situated in the proximity of the first area of contact 435 is active and switches between an amorphous and a crystalline phase. In order to control the resistance of the memory element, the amount of phase-change material that actually changes phase may be controlled.

Increased control over the volume fraction of amorphous to crystalline material may be accomplished by designing a memory device structure (the shapes, sizes and compositions of materials as well as the structural relationship between the components) which is effective to provide non-uniform heating of the phase-change material about the area of contact. Such non-uniform heating creates a non-uniform temperature profile in the phase-change material about the area of contact 435. Non-uniform heating of the phase-change material results in non-uniform crystallization of the phase-change material about the area of contact so that the volume percentage of amorphous material to crystalline material can be more accurately controlled.

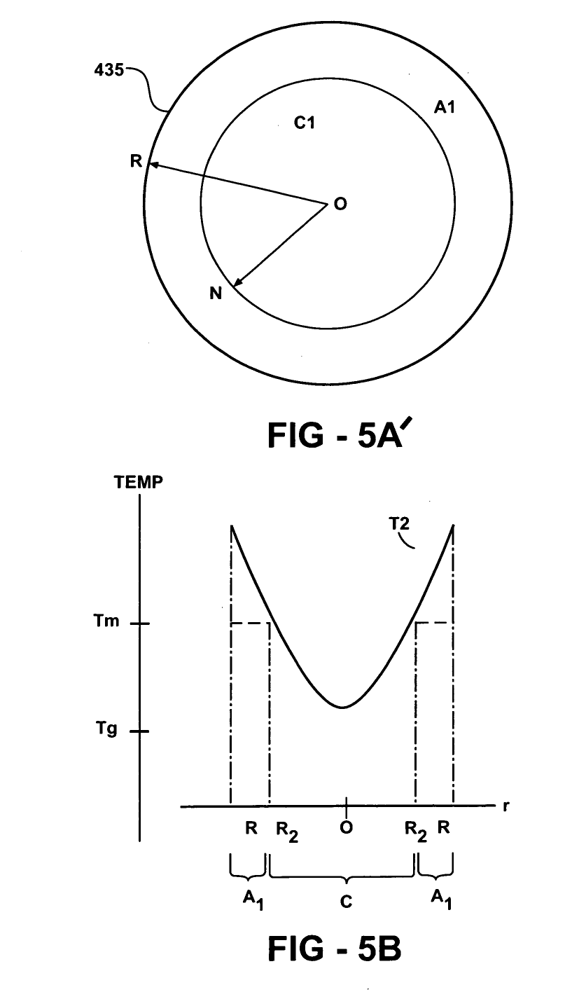

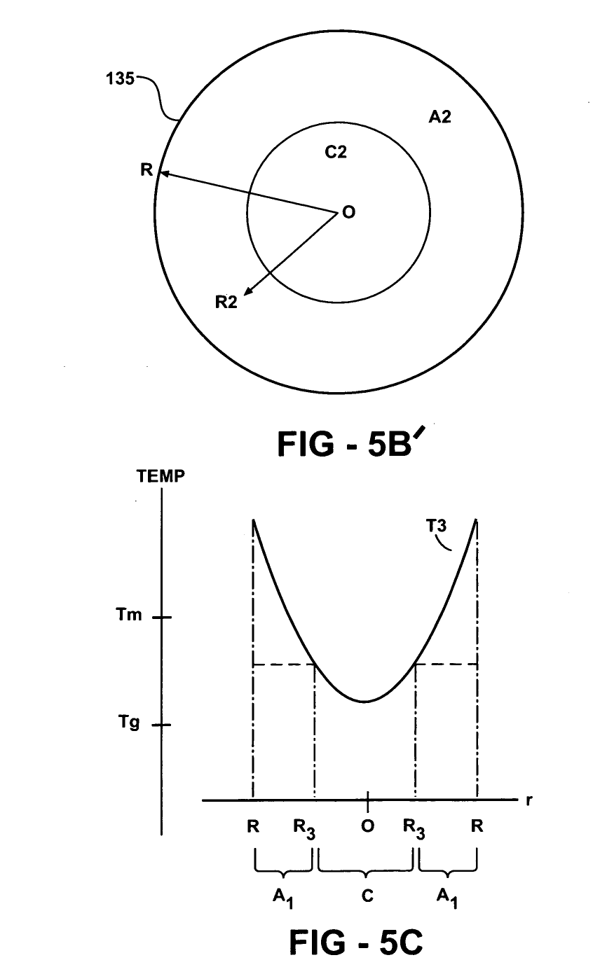

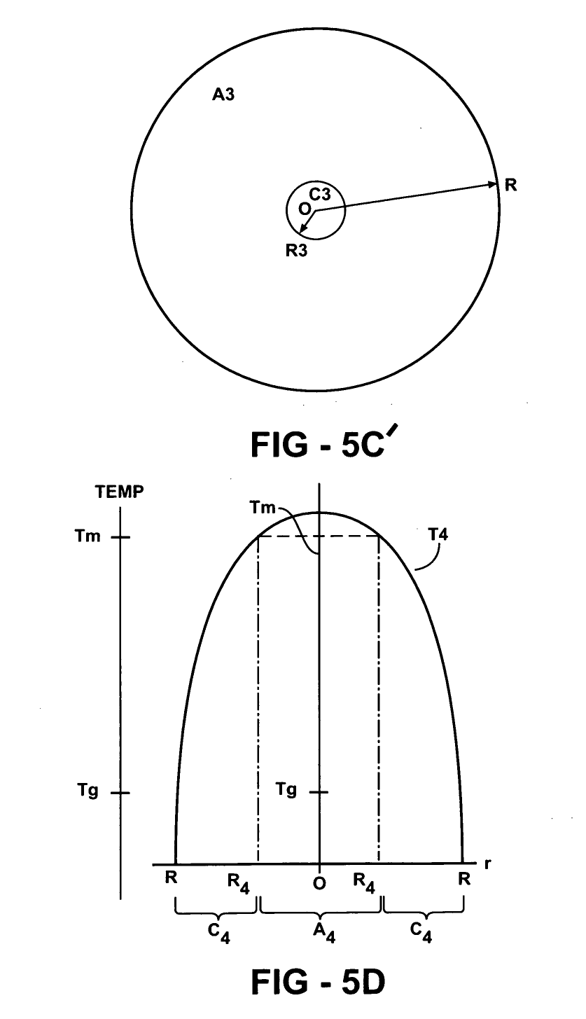

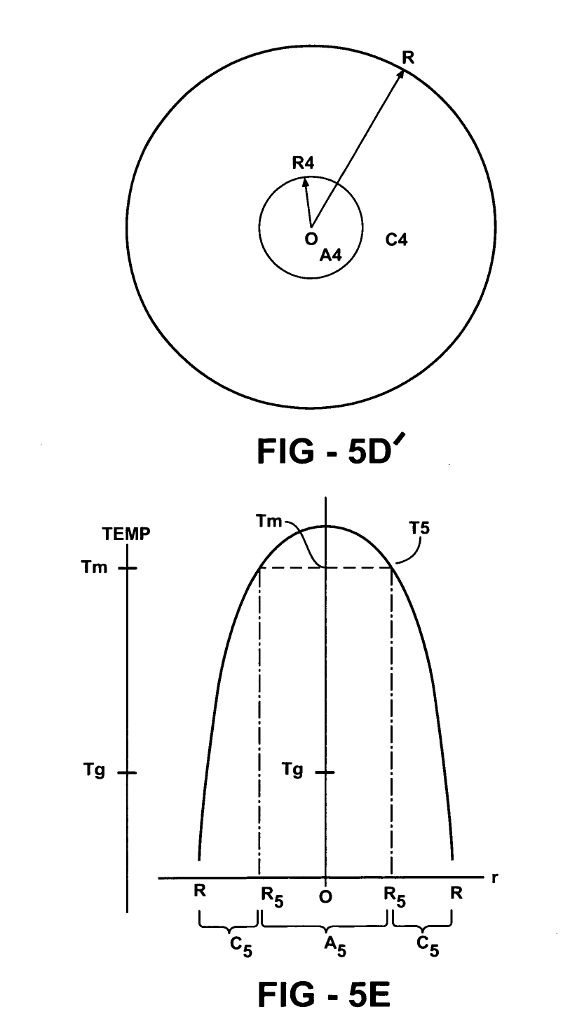

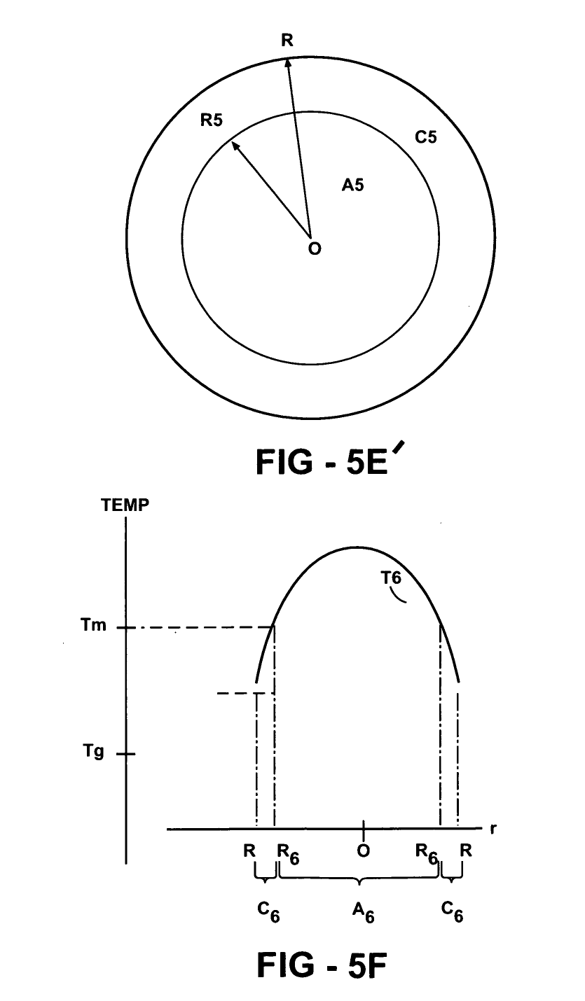

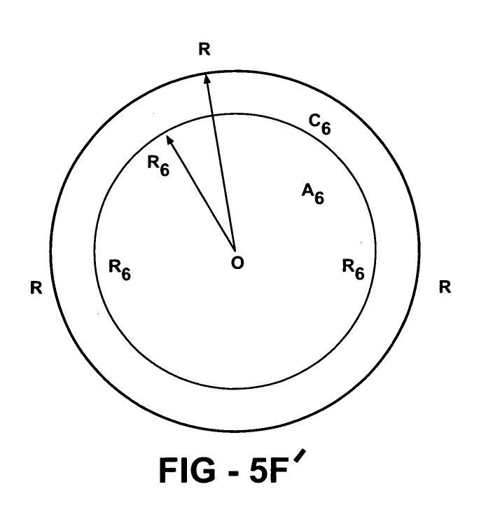

Generally, any non-uniform temperature profile may be used in the present invention. One example of a non-uniform temperature profile is shown in FIG. 5A. In this example, the temperature Temp of the phase-change material about the area of contact 435 is shown as a function of the lateral cross-section of the area of contact 435. The dimension r on the horizontal axis represents the radial distance from the center 0 of the area of contact. In the FIG. 5A, it is shown that the temperature at the periphery of the area of contact 435 (at a radial distance r=R from the center) is the highest while the temperature at the center of the area of contact (at r=0) is the lowest. Additionally, FIG. 5A shows a temperature profile T1 of the phase-change material which opens upward (e.g. is concave upward) such that the temperature is greater proximate to the periphery of the area of contact 435 and lesser remote to the periphery of the area of contact. Generally, the shape of the temperature profile is not limited to any particular shape and may, for example, be conical, hemi-spherical and paraboloid.

Hence, FIG. 5A shows the temperature profile T1 of the temperature Temp of the phase-change material at the area of contact 435 as a function of the radial distance r from the center of the area of contact 435. In the temperature profile T1 shown in FIG. 5A, the temperature from radial distance r=0 to radial distance r=r1 is less than the temperature Tm but greater than the temperature Tg, where Tm is the melting temperature of the phase-change material and Tg is the crystallization temperature (e.g., the glass transition temperature) of the phase-change material. Likewise, the temperature T1 is greater than Tm from r1 to R (where R is the radius of the area of contact 435).

FIG. 5A′ shows a top view of the phase-change material about the area of contact 435. FIG. 5A′ shows that from radial distance 0 to r1, the active phase-change material is in a substantially crystalline state as represented by crystalline region C1. Likewise, FIG. 5A′ shows that from radial distance r1 to R, the active phase-change material at the area of contact 435 is in a substantially amorphous state as represented by amorphous region A1. Hence, it is seen that in the active phase-change material at the area of contact 435, a volume fraction of the phase-change material is a crystalline region C1 and a volume fraction is an amorphous region A1. The resistance state of the memory element may be represented by a resistance state RA.

FIG. 5B shows a second temperature profile T2 of the active phase-change material at the area of contact 435. This profile T2 has the same shape as temperature profile T1 except that it is shifted up. In the temperature profile T2 shown in FIG. 5B, the temperature from radial distance 0 to r2 is less than the temperature Tm but greater than the temperature Tg (where, again, Tm is the melting temperature of the phase-change material and Tg is the crystallization temperature of the phase-change material). Likewise, the temperature T2 is greater than Tm from radial distance r2 to R. In the case of temperature profile T2, radial distance r2 is less than the radial distance r1.

FIG. 5B′ shows a top view of the phase-change material at the area of contact 435. FIG. 5B′ shows that from radial distance 0 to r2 (where r2 is less than r1), the phase-change material at the area of contact 435 is in a substantially crystalline state as represented by crystalline region C2. Likewise, FIG. 5B′ shows that from radial distance r2 to R, the phase-change material at the area of contact 435 is in a substantially amorphous state as represented by amorphous region A2. The phase-change material at the area of contact 435 has a volume fraction in a crystalline region C2 and a volume fraction in an amorphous region A2. The resistance state of the memory element may be represented by a resistance state RB. The resistance RB is greater than the resistance RA.

FIG. 5C shows a third temperature profile T3 of the active phase-change material at the area of contact 435. This profile T3 has the same shape as temperature profile T1 and T2 except that it is shifted up from T2. In the temperature profile T3 shown in FIG. 5C, the temperature from radial distance 0 to r3 is less than the temperature Tm but greater than the temperature Tg. Likewise, the temperature T3 is greater than Tm from radial distance r3 to R. Distance r3 is less than distance r2.

FIG. 5C′ shows a top view of the phase-change material at the area of contact 435. FIG. 5C′ shows that from 0 to distance r3 (which is less than r2), the active phase-change material is in a substantially crystalline state as represented by crystalline region C3. Likewise, FIG. 5C′ shows that from radial distance r3 to R, the active phase-change material at the area of contact is in a substantially amorphous state as represented by amorphous region A3. The active phase-change material at the area of contact 435 has a volume fraction of the phase-change material is a crystalline region C3 and a volume fraction is an amorphous region A3. The resistance state of the memory element may be represented by a resistance state RC. The resistance of RC is greater than that of the resistance state RB.

The temperature profiles TA, TB and TC shown in FIGS. 5A, 5B and 5C, respectively, show that a peripheral portion of the area of contact is heated to a higher temperature than a central portion. In order to accomplish this, the memory device may be designed so that this occurs.

As an example, FIG. 4B shows a memory device like that of FIG. 4A such that the current lines are directed through the top electrode 450 and bottom electrode 420 so as to crowd about a peripheral portion of the area of contact. In addition to crowding the current lines about the periphery of the area of contact, the structure of the memory device shown in FIG. 4B may be adapted to cause the non-uniform temperature profiles shown in FIGS. 5A, 5B and 5C. For example, the top electrode 450 may be made to be relatively thick. A relatively thick top electrode behaves as a good heat sink thereby sinking a large amount of heat from the phase-change material 440. This helps to prevent the central portion of the phase-change material from getting too hot. In addition, the phase-change 440 may be made to be relatively thin. A relatively thin phase-change material layer may cause more of the heat in the phase-change material to escape from the phase-change material and into the top electrode. In addition, the width or diameter of the opening 432 (for example, a hole or pore) may be made to be relatively large. A larger pore provides for a larger area of contact 435. The larger area of contact makes it more difficult for the heat from the periphery to quickly spread to the central portion of the area of contact. Hence, the larger area of contact promotes a non-uniform temperature profile. The width of the area of contact (for example, the diameter of the opening or pore) may be sized in relation to the feature size of the device. The feature size of the device may be denoted as F. The feature size F may be the photolithographic limit of the processing technology. In one embodiment of the invention, the width of the area of contact may be greater than or equal to about (⅔)F.

One way to stably control the resistance of the phase-change memory element, is to control the amount of material changing phase. In a planar device, such as the devices shown in FIGS. 4A and 4B, this can be controlled by the vertical heat loss through the upper electrode 450 and the lower electrode 420. It is noted that these electrode may be thermally resistive enough to provide sufficient heating of the phase-change material to provide low power. However, may also be thermally conductive enough so that the vertical heat conduction leads to a substantial non-uniformity between the center and edge of the area of contact 435 of the device.

The thermal conductivity of the electrodes 450, 420 may be varied, for example, by varying the resistivity of the electrode material and/or the dimensions (e.g. the thicknesses) of the electrode material. The thicknesses of one or both of the electrodes may be varied to provide improved multi-state operation. For example, while not wishing to be bound by theory, it is believed that a thicker top electrode and/or bottom electrode creates greater heat sinking which may be better for multi-state operation since it may create less uniform heating in the phase-change material about the area of contact. In an embodiment of the invention, the thickness of the conductive layer 450 (e.g. the top electrode) may be made thicker than the thickness of the phase-change layer 440. In another embodiment of the invention, the thickness of the conductive layer 420 (e.g. the bottom electrode) may be made thicker than the thickness of the phase-change layer 440.

Likewise, varying the width of the opening 432, thereby creating a larger area of contact 435 between the bottom electrode 420 and the phase-change material also provides for increased non-uniformity of the heating of the phase-change material about the area of contact 435. As noted above, in one embodiment of the invention, the width of the opening 432 may be made to greater than or equal to about (⅔)F where F is the feature size of the device. In another embodiment of the invention, the width of the opening 432 may be greater than the feature size F.

FIG. 4C shows a phase-change memory element 50 comprising a substrate 500, a bottom electrode 520 embedded in a dielectric material 510. A phase-change material 540 is formed on top of the electrode 520 such that the phase-change material 540 is in electrical communication with the bottom electrode 520. Phase-change material 540 and the bottom electrode 535 have an area of contact 535. Electrode 550 forms a top electrode for the memory element 50.

In the example shown in FIG. 4C, the heating of the phase-change material begins at the central portion of the area of contact 535 and the phase-change material adjacent the area of contact has a higher temperature close to the center than it does closer to the periphery of the area of contact.

In the example shown in FIG. 4C, the device 50 uses a relatively thick top electrode as a heat sink, a relatively thin layer of phase-change material 540 so that the heat may quickly escape from the phase-change material. Hence, the memory device 50 is relatively poorly insulated. In addition, the memory device 50 also uses a bottom electrode 520 having a relatively thick lateral cross section so that the area of contact 535 is relatively large. In the embodiment shown, the lateral cross section of the bottom electrode 520 has a radius of R2.

The device shown in FIG. 4C may be so adapted to create a non-uniform temperature profile in the phase-change material about the area of contact 535. For example, the temperature profiles shown in FIGS. 5D, 5E and 5F may be created. Referring to FIG. 5D, in this example, the temperature of the phase-change material about the area of contact 535 is also shown as a function of the lateral cross-section of the area of contact 535. In the example of FIG. 5D, it is shown that the temperature at the center of the area of contact 535 is the highest while the temperature at the periphery of the area of contact is the lowest. Additionally, FIG. 5D shows a temperature profile T4 of the phase-change material which opens downward (e.g. is concave downward) such that the temperature is lesser proximate to the periphery of the area of contact and greater remote to the periphery of the area of contact. Generally, the shape of the temperature profile is not limited to any particular shape and may, for example, be conical, hemi-spherical and paraboloid.

FIG. 5D shows the temperature profile T4 across the area of contact 535 as a function of the distance r from the center. In the temperature profile T4 shown in FIG. 5D, the temperature from 0 to r4 is greater than the temperature Tm. Likewise, the temperature T4 is less than Tm but greater than Tg from r4 to R2.

FIG. 5D′ shows a top view of the phase-change material about the area of contact 535. FIG. 5D′ shows that from 0 to radius r4, the active phase-change material is in a substantially amorphous state as represented by crystalline region A4. Likewise, FIG. 5D′ shows that from radius r4 to R, the active phase-change material about the area of contact is in a substantially crystalline state as represented by crystalline region C4. Hence, it is seen that in the active phase-change material about the area of contact 535, a volume fraction of the phase-change material is a crystalline region C4 and a volume fraction is an amorphous region A4. The resistance state of the memory element may be represented by a resistance state RSD.

FIG. 5E shows another temperature profile T5 of the active phase-change material about the area of contact 535. This profile T5 has the same shape as temperature profile T4 except that it is shifted up. In the temperature profile T5 shown in FIG. 5E, the temperature from 0 to r5 is greater than the temperature Tm. Likewise, the temperature T5 is less than Tm but greater than Tg from r5 to R.

FIG. 5E′ shows a top view of the phase-change material about the area of contact 535. FIG. 5E′ shows that from 0 to radius r5 (which is greater than r4), the active phase-change material is in a substantially amorphous state as represented by amorphous region A5. Likewise, FIG. 5E′ shows that from radius r5 to R, the active phase-change material about the area of contact is in a substantially crystalline state as represented by crystalline region C5. The active phase-change material about the area of contact 535 has a volume fraction of the phase-change material in an amorphous region A5 and a crystalline region C5 and a state of the memory element may be represented by a resistance state RE. The resistance RE is greater than the resistance RD.

FIG. 5F shows another temperature profile T6 of the active phase-change material about the area of contact 435. This profile T6 has the same shape as temperature profile T4 and T5 except that it is shifted up from T6. In the temperature profile T6 shown in FIG. 5F, the temperature from 0 to r6 is greater than the temperature Tm. Likewise, from r6 to R the temperature T6 is less than Tm but greater that Tg.

FIG. 5F′ shows a top view of the phase-change material about the area of contact 435. FIG. 5F′ shows that from 0 to radius r6 (which is greater than r5), the active phase-change material is in a substantially amorphous state as represented by the amorphous region A6. Likewise, FIG. 6F′ shows that from radius r6 to R, the active phase-change material about the area of contact is in a substantially crystalline state as represented by crystalline region C6. The active phase-change material about the area of contact 435 has a volume fraction of the phase-change material is a crystalline region C6 and a volume fraction is an amorphous region A6. The resistance state of the memory element may be represented by a resistance state RF. The resistance of RF is greater than that of the resistance state RE.

The temperature profiles T4, T5 and T6 shown in FIGS. 5D, 5E and 5F show that a central portion of the area of contact is heated to a higher temperature than a peripheral portion. In order to accomplish this, a memory device may be so designed so that this occurs. For example, FIG. 4C shows a memory device that may appropriately adapted to create temperature profiles like those shown in FIG. 5D through 5F.

Another way to provide for a non-uniform temperature profile in the phase-change material about the area of contact is to increase the aspect ratio (e.g. length to width) of the area of contact between the electrode and the active phase-change material.

Changing the structure of the memory element as well as the characteristics of the memory element components (e.g. thickness of the top electrode, resistivity of the top electrode, thickness of the phase-change material, size of the area of contact, aspect ratio of the area of contact, etc) changes the shape of the I-R curve shown in FIG. 1A. For example, by adapting the structure so as to provide a non-linear temperature profile, tends to flatten (e.g. reduce the slope) of the right side of the I-R curve.

Referring to FIG. 1A, it is seen that the right side of the I-R curve may be reversibly programmed between different resistance states. Programming occurs as a result of applying a programming pulse where each of the programming pulses has an amplitude sufficient to melt some volume fraction of the phase-change material in the active region of the phase-change material about the area of contact.

The current amplitude I_{MELT} is the amplitude of a programming current pulse which is the minimum current that is sufficient to cause the melting of at least a portion of the chalcogenide material about the area of contact. It is seen that as the amplitude of the programming current pulse continues to increase above I_{MELT}, the programmed resistance along the right side of the I-R curve continues to rise. The rise is substantially linear until saturation is reached at which point, the slope of the I-R curve begins to decrease. As shown in FIG. 1A, the amplitude of the current programming pulse needed to reach saturation may be described as I_{SAT}. In one embodiment of the invention I_{SAT} may be the current amplitude at which 90% of the maximum resistance reached on the right side of the I-R curve.

In an illustrative embodiment, the ratio of I_{SAT} to I_{MELT} is about 1.5 to 1. However, the ratio of I_{SAT} to I_{MELT} may be increased by increasing the non-uniformity of the temperature profile about the area of contact. Hence, in one embodiment of the invention, the ratio of I_{SAT} to I_{MELT} may be at least 3 to 1. In another embodiment, the ratio of I_{SAT} to I_{MELT} may at least 4 to 1. In yet another embodiment, the ratio of I_{SAT} to I_{MELT} may be at least 6 to 1. As seen, increasing the ratio of I_{SAT} to I_{MELT}, flattens (e.g. lessens the slope) of the right side of the I-R curve so as to provide for improved multi-state operation.

There are yet other ways to improve the multi-state behavior of a phase-change memory element. This is to provide a thermal inhomogeniety in the vicinity of the area of contact, causing non-uniform heat flow. For example a memory element similar to that shown in FIG. 4C may include a dielectric layer formed above the top electrode 550 to provide additional thermal insulation, if desired. A portion of the dielectric layer may be replaced by a conductive layer that is both electrically and thermally conductive.

The thermal conductivity of the conductive layer behaves as a heat sink so as to draw away heat from the active region of the phase-change material. Hence, the heat flow within the bulk of the phase-change material is uneven or asymmetric such that there is more heat flow from the phase-change material to the conductive material and less heat flow from the phase-change material to the insulative material. Hence, the region of the phase-change material in the proximity of the conductive material becomes cooler at a faster rate so as to provide a region of increased quenching of the phase-change material. This region of increased quenching results in an asymmetric region of amorphous material within the region of phase-change material. While not wishing to be bound by theory, it is believed that the asymmetry of this region of amorphous material results in flattening the right side of the I-R curve shown in FIG. 1A, thereby resulting in improved multi-state behavior.

Examples of the materials which may be used for top and bottom electrodes described herein include, but are not limited to, titanium nitride, titanium aluminum nitride, titanium carbonitride, titanium silicon nitride, molybdenum, carbon, tungsten, tungsten silicide, titanium-tungsten, n-type doped polysilicon, p-type doped polysilicon, n-type doped silicon carbon compounds and/or alloys, p-type doped silicon carbon compounds and/or alloy.

Examples of materials which may be used as the dielectric or insulative layers include oxides and nitrides. Examples of oxide include silicon oxide. Examples of nitrides include silicon nitride.

The memory material may be a phase-change material. The phase-change materials may be any phase-change memory material known in the art. The phase-change materials may be capable of exhibiting a first order phase transition. Examples of materials are described in U.S. Pat. Nos. 5,166,758, 5,296,716, 5,414,271, 5,359,205, 5,341,328, 5,536,947, 5,534,712, 5,687,112, and 5,825,046 the disclosures of which are all incorporated by reference herein.

The phase-change materials may be formed from a plurality of atomic elements. Preferably, the memory material includes at least one chalcogen element. The chalcogen element may be chosen from the group consisting of Te, Se, and mixtures or alloys thereof. The memory material may further include at least one element selected from the group consisting of Ge, Sb, Bi, Pb, Sn, As, S, Si, P, O, and mixtures or alloys thereof. In one embodiment, the memory material comprises the elements Te, Ge and Sb. In another embodiment, the memory material consists essentially of Ge, Sb and Te. An example of a memory material which may be used is Ge₂Sb₂Te.

The memory material may include at least one transition metal element. The term “transition metal” as used herein includes elements 21 to 30, 39 to 48, 57 and 72 to 80. Preferably, the one or more transition metal elements are selected from the group consisting of Cr, Fe, Ni, Nb, Pd, Pt and mixtures or alloys thereof. The memory materials which include transition metals may be elementally modified forms of the memory materials in the Te—Ge—Sb ternary system. This elemental modification may be achieved by the incorporation of transition metals into the basic Te—Ge—Sb ternary system, with or without an additional chalcogen element, such as Se.

It is to be understood that the disclosure set forth herein is presented in the form of detailed embodiments described for the purpose of making a full and complete disclosure of the present invention, and that such details are not to be interpreted as limiting the true scope of this invention as set forth and defined in the appended claims.

We claim:

1. A phase-change memory, comprising:
a volume of phase change material; and
a thermal element in thermal communication with the volume of phase change material, the thermal element configured to preferentially shape the volume portion of phase change material that is amorphized in response to the passing of a current pulse through the phase change material.

2. The phase-change memory of claim 1 wherein the thermal element is configured to impose a thermal non-uniformity upon the phase change material.

3. The phase-change memory of claim 2 wherein the thermal non-uniformity is configured to increase the volume fraction of phase change material amorphized for a given increase in the amplitude of a programming current without decreasing the RESET current of the device.

4. The phase-change memory of claim 1 wherein the thermal element is configured to direct energy to preferentially amorphize a volume of phase change material that is not determinative of the phase change memory's RESET current.

5. The phase-change memory of claim 1 wherein the thermal element is configured to retard amorphization along a path of least resistance within the volume of phase change material.

6. The phase change memory of claim 1 wherein the thermal element operates as a heat dissipating device.

7. The phase change memory of claim 1 wherein the thermal element operates as a heat conserving device.

8. The phase change memory of claim 6 wherein the thermal element is an electrode.

9. The phase change memory of claim 6 wherein the thermal element is an address line.

10. The phase change memory of claim 7 wherein the thermal element is device insulation.

11. The phase change memory of claim 6 wherein the thermal element is an absence of insulation.

12. The phase change memory of claim 1 comprising a plurality of thermal elements in thermal communication with the phase change material.

13. The phase change memory of claim 12 wherein at least one thermal element is heat dissipative.

14. The phase change memory of claim 12 wherein at least one thermal element is heat conservative.

15. The phase change memory of claim 1 further comprising a heater.

16. The phase change memory of claim 1 wherein the thermal element imposes a lateral thermal non-uniformity on the phase change material.

17. The phase change memory of claim 1 wherein the thermal element imposes a vertical thermal non-uniformity on the phase change material.

18. A phase change memory comprising:
a phase-change material; and
an electrode in electrical communication with said phase-change material, said phase-change material and said electrode having an area of contact, said memory element being adapted so that application of an energy to said memory element creates a non-uniform temperature profile in the phase-change material about said area of contact.

19. The memory of claim 18, wherein said area of contact has a periphery, said temperature profile being characterized by a first temperature proximate said periphery and a second temperature remote said periphery, said first temperature being greater than said second temperature.

20. The memory element of claim 18, wherein said area of contact has a periphery, said temperature profile being characterized by a first temperature proximate said periphery and a second temperature remote said periphery, said first temperature being less than said second temperature.

21. The memory element of claim 18, wherein said phase-change material comprises a chalcogen element.

22. A memory element, comprising:
a phase-change material;
a heat source in thermal communication with said phase-change material, said heat source providing thermal energy to said phase-change material; and
a heat dissipative element in thermal communication with said phase-change material, said heat dissipative element configured to remove thermal energy from said phase-change material, said heat dissipative element being asymmetrically positioned relative to said heat source.

23. The memory element of claim 22, where there is asymmetric heat flow between said heat source and said heat dissipative element.

24. The memory element of claim 22, wherein said heat flow is asymmetric relative to a vertical plane about the heat source.
